(19) United States
(12) Patent Application Publication
(10) Pub. No.: US 2020/0105736 A1
(43) Pub. Date: Apr. 2, 2020

(54) 3D Stacked and Encapsulated LED Display Screen Module and Its Encapsulation Method

(71) Applicants: Bo TU, Guangdong (CN); Hsiang-Yi CHENG, Guangdong (CN)

(72) Inventors: Bo TU, Guangdong (CN); Hsiang-Yi CHENG, Guangdong (CN)

(21) Appl. No.: 16/578,417

(22) Filed: Sep. 23, 2019

(30) Foreign Application Priority Data
Sep. 28, 2018 (CN) 201811141934.1
Aug. 21, 2019 (CN) 201910771479.1

(51) Int. Cl. H01L 25/18; H01L 33/62; H01L 23/00; H01L 25/00

(52) U.S. Cl. CPC H01L 25/18; H01L 33/62; H01L 24/32; H01L 24/33; H01L 25/50; H01L 2924/12041; H01L 2224/32145; H01L 2224/32225; H01L 2224/33181; H01L 2933/0066; H01L 24/83

(57) ABSTRACT

The invention discloses a three-dimensional stacked encapsulated LED display screen module and its encapsulation method thereof. The LED display screen module comprises a transparent screen substrate on the surface of the display screen, wherein a red LED layer, a green LED layer, a blue LED layer and an LED light emitting control device layer positioned on them are sequentially stacked in any order on the transparent screen substrate. The translucent screen substrate, the red light LED layer, the green light LED layer, the blue light LED layer and the LED light emitting control device layer are fixedly connected through shadowless adhesive layers. Conductive circuits formed by carving or etching metal films or alloy films are laid on various layers, and LEDs are arranged on different layers in a staggered manner.

### BACKGROUND OF THE INVENTION

The invention relates to the technical field of chip encapsulation, in particular, to a 3D stacked and encapsulated LED display screen module and its encapsulation method.

At present, LED display screens on the market generally adopt in-line encapsulating technology or patch encapsulating technology. Due to the limitations of the two encapsulating technologies, a bracket must be used in the encapsulated structure. As the combination of red, green and blue LEDs is used as a pixel point, the structure of the bracket will cause the spacing of each pixel point to be too large, and therefore the display resolution will be relatively low and the display effect will not be exquisite enough. At present, MiNi LED or MiCRO LED is limited in pixels due to the restriction of wire bonding or flip-chip process. Now, it can achieve P0.8, that is, the distance between each center point is 0.8 mm. In the prior art, the independent single LED chips are sucked and then transferred integrally (in a large amount) while manufacturing the LED display screen modules, so there are problems of how to make the spacing between the LED chips arranged on the LED display screen module small and how to achieve die bonds at a small spacing.

### BRIEF SUMMARY OF THE INVENTION

The technical problem to be solved by the invention is to provide a three-dimensional stacked encapsulated LED display screen module and its encapsulation method thereof so as to overcome the defects of too large pixel point spacing, relatively low display resolution and insufficient exquisite display effect caused by the encapsulating process of the LED display screen in the prior art.

The invention adopts the following technical solution to solve the technical problems:

A three-dimensional stacked encapsulated LED display screen module, which comprises a translucent screen substrate on the surface of the display screen, wherein a red LED layer, a red LED layer, a green LED layer, a blue LED layer and a LED light-emitting control device layer positioned above the red LED layer, the green LED layer and the blue LED layer are sequentially stacked in any order on the translucent screen substrate. The translucent screen substrate, the red light LED layer, the green light LED layer, the blue light LED layer and the LED light emitting control device layer are fixedly connected through shadowless glue layers. Conductive circuits formed by carving or etching metal films or alloy films are laid on the red light LED layer, the green light LED layer, the blue light LED layer and the LED light emitting control device layer, and LEDs are arranged on different layers in a staggered manner.

According to the embodiment of the invention, the translucent screen substrate is toughened glass or transparent plastic plate.

According to the embodiment of the invention, the metal film or the alloy film is formed by utilizing the vacuum evaporation plating technology, magntron sputtering technology, continuous coating technology, hydro-electric coating technology or chemical coating technology.

According to the embodiment of the invention, the conductive circuit is formed via the laser carving technology.

According to the embodiment of the invention, the LED light-emitting control device layer is covered with an encapsulating glue layer.

An encapsulation method of LED display screen module, which comprises the steps:

A1. Apply a layer of shadowless glue on the translucent screen substrate;

A2. A red LED layer, a green LED layer and a blue LED layer are sequentially stacked in any order, wherein LEDs on different layers are arranged in a staggered manner; shadowless glue layers are applied between the red LED layer, the green LED layer and the blue LED layer, and simultaneously a metal film or an alloy film is fabricated around the LEDs on each shadowless glue layer. The metal film or the alloy film is carved or etched to form a conductive circuit;

A3. Re-apply a layer of shadowless glue;

A4. Stack the LED light-emitting control device layer, and simultaneously fabricate the metal film or alloy film around the LED light emitting control device. Carve or etch the metal film or the alloy film to form a conductive circuit;

A5. Cover an encapsulated glue layer above the LED light-emitting control device layer.

According to the embodiment of the invention, the translucent screen substrate is toughened glass or transparent plastic plate.

According to the embodiment of the invention, the metal film or the alloy film is formed by utilizing the vacuum evaporation plating technology, magntron sputtering technology, continuous coating technology, hydro-electric coating technology or chemical coating technology.

According to the embodiment of the invention, the conductive circuit is formed via the laser carving technology.

According to the embodiment of the invention, the encapsulating glue layer is a shadowless glue layer.

According to the embodiment of the invention, Step A2 comprises the following steps:

B1. LED chips are sucked via the die bond and arranged and placed on the plane adhesive board. The plane adhesive board is buckled upside down on the shadowless glue layer for pressing and solidifying;

B2. The plane adhesive board is pulled out to ensure that all LED chips remain flush on the shadowless glue layer.

An LED display screen module stacked and encapsulated by blocks, which comprises the translucent screen substrate on the surface of display screen. A red LED layer, a green LED layer, a blue LED layer and an LED light emitting control device layer positioned above the red LED layer, the green LED layer and the blue LED layer are sequentially stacked in any order on the translucent screen substrate. The red LED layer consists of a red LED chipset block which can be transferred and placed integrally, the green LED layer consists of a green LED chipset block which can be transferred and placed integrally, the blue LED layer consists of a blue LED chipset block which can be transferred and placed integrally. The translucent screen substrate, the red light LED layer, the green light LED layer, the blue light LED layer and the LED light emitting control device layer are fixedly connected through shadowless glue layers. Conductive circuits formed by carving or etching metal films or alloy films are laid on the red light LED layer, the green light LED layer, the blue light LED layer and the LED light emitting control device layer.

According to the embodiment of the invention, the red LED chipset, the green LED chipset and the blue LED chipset are composed of LED chips of 10*10, 20*20, 30*30 or 40*40, respectively.

According to the embodiment of the invention, the red LED chipset block, the green LED chipset block and the blue LED chipset block are manufactured by adopting a photomask technology.

According to the embodiment of the invention, shallow channels are arranged on the peripheries of the red LED layer, the green LED layer and the blue LED layer.

According to the embodiment of the invention, shallow channels are arranged on the peripheries of the red LED chipset block, the green LED chipset block and the blue LED chipset block.

According to the embodiment of the invention, shallow channels are arranged on the periphery of the LED chipsets.

According to the embodiment of the invention, LED chips on the red LED layer, the green LED layer and the blue LED layer are subject to the positive pole common connection, and each row or each column of LED chips on the red LED layer, the green LED layer and the blue LED layer are subject to the negative pole common connection.

An encapsulation method of LED display screen module, which comprises the steps:

C1. Apply a layer of shadowless glue on the translucent screen substrate;

C2. The red LED layer consists of a red LED chipset block which can be transferred and placed integrally, the green LED layer consists of a green LED chipset block which can be transferred and placed integrally and the blue LED layer consists of a blue LED chipset block which can be transferred and placed integrally.

C3. A red LED layer, a green LED layer and a blue LED layer are sequentially stacked in any order. Shadowless glue layers are applied between the red LED layer, the green LED layer and the blue LED layer, and simultaneously a metal film or an alloy film is fabricated around the LEDs on each shadowless glue layer. The metal film or the alloy film is carved or etched to form a conductive circuit;

C4. Re-apply a layer of shadowless glue;

C5. Stack the LED light-emitting control device layer, and simultaneously fabricate the metal film or alloy film around the LED light emitting control device. Carve or etch the metal film or the alloy film to form a conductive circuit;

C6. Cover an encapsulated glue layer above the LED light-emitting control device layer.

The invention has the advantages: the invention adopts a new technology of bonding-wire-free encapsulated front side of three-dimensional stacked LED chips, with one side being an LED luminous surface and the other side a wire connecting surface, to form a tight module layout and make the LED display screen module to be stripped of the substrate and the frame so as to improve the pixels per unit area and the resolution of the display screen, and therefore the display effect is better and more exquisite. Glue is used to replace the bracket while encapsulating. The screen point spacing without the bracket structure is less than 0.1 mm, thus reducing the spacing between LEDs and improving the display effect. In the encapsulating process of the display module, the bonding wire is replaced by sputtering to increase the reliability of the product. The invention further adopts a new process of arranging the LED chips by LED chipset blocks. This thus reduces the technical difficulty of carrying out massive transfer while manufacturing the LED display screen module, and simultaneously it can reduce the spacing of LED chips, decrease the die-bond difficulty of the LED chips with small spacing and further improve the resolution of the display screen, and furthermore it can increase the reliability of the product, lower the labor cost and further improve the reliability.

### BRIEF DESCRIPTION OF THE DRAWINGS

Advantages and embodiments of the invention will become more apparent when the invention is described in detail below with reference to the drawings and in combination with the embodiments; the contents shown in the drawings are only for the explanation of the invention and do not constitute any limitation to the invention in any sense; in the drawings:

FIG. 1 is a schematic diagram of the stacked structure of a LED display screen module of the invention;

FIG. 2 is a schematic diagram of the arrangement structure of the red, green and blue LEDs of the invention;

FIG. 3 is a schematic diagram of the shadowless glue layer of the invention;

FIG. 4 is a schematic diagram of a conductive circuit on the LED light-emitting control device layer of the invention;

FIG. 5 is a schematic diagram of an LED light-emitting control device layer of the invention;

FIG. 6 is a schematic diagram of a conductive circuit on the red, green and blue LED layers of the invention;

FIG. 7 is a schematic diagram of the pin connection mode of the LED chips of the invention;

FIG. 8 is a schematic diagram of the red, blue and green LED layers of the invention.

### DETAILED DESCRIPTION OF THE INVENTION

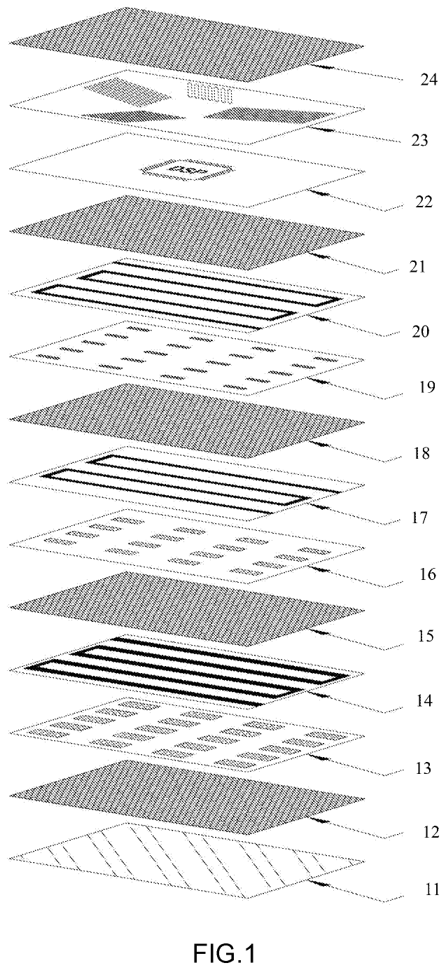

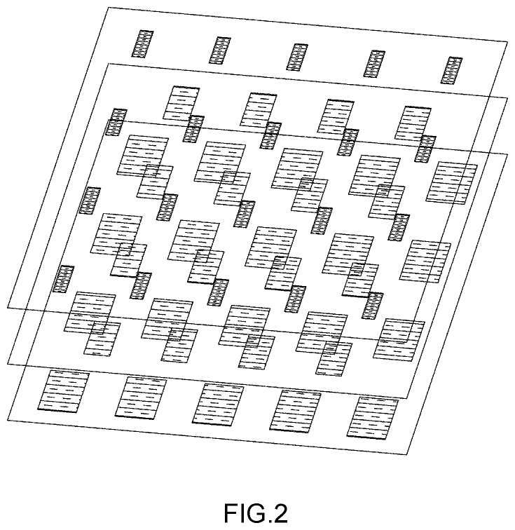

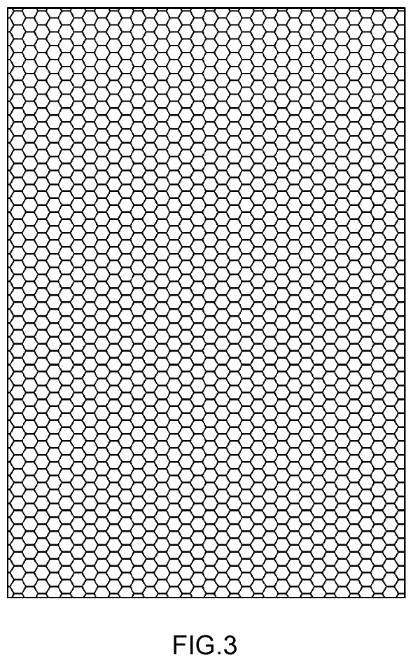

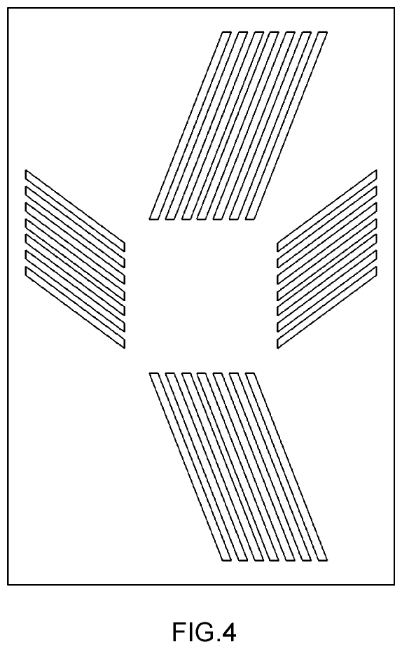

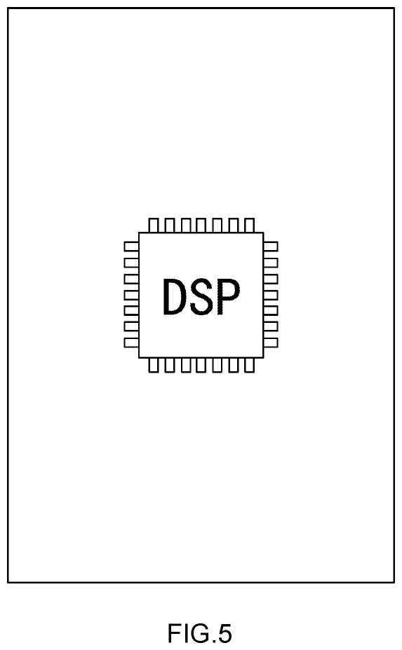

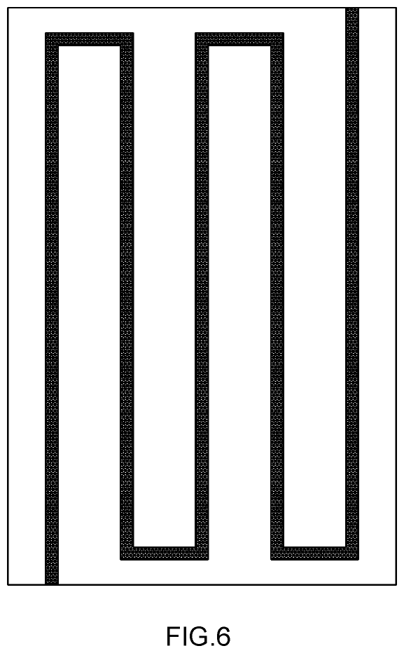

As shown in FIG. 1, FIG. 2, FIG. 3, FIG. 4, FIG. 5 and FIG. 6, the three-dimensional stacked encapsulated LED display screen module in the invention comprises a translucent screen substrate 11 on the surface of a display screen, wherein a red LED layer 13, a green LED layer 16, a blue LED layer 19 and an LED light emitting control device layer 22 positioned above the red LED layer 13, the green LED layer 16 and the blue LED layer 19 are sequentially stacked in any order on the translucent screen substrate 11. The translucent screen substrate 11, the red light LED layer 13, the green light LED layer 16, the blue light LED layer 19 and the LED light emitting control device layer 22 are fixedly connected through the shadowless glue layers 12, 15, 18 and 21; the red LED layer 13, the green LED layer 16 and the blue LED layer 19 are coated with the metal films 14, 17, 20 and 23, respectively. Conductive circuits formed by carving or etching metal films or alloy films are laid on the red light LED layer, the green light LED layer, the blue light LED layer and the LED light emitting control device layer, and LEDs are arranged on different layers in a staggered manner. According to the embodiment of the invention, the translucent screen substrate 11 is a toughened glass or transparent plastic plate. The metal film or the alloy film is formed by utilizing the vacuum evaporation plating technology, magntron sputtering technology, continuous coating technology, hydro-electric coating technology or chemical coating technology. The conductive circuit is formed via the laser carving technology. LED light-emitting control device layer 22 is covered with the encapsulated glue layer 24.

The encapsulation method of LED display screen module in the invention comprises the steps:

A1. Apply a layer of shadowless glue 12 on the translucent screen substrate 11;

A2. A red LED layer 13, a green LED layer 16 and a blue LED layer 19 are sequentially stacked in any order, wherein LEDs are arranged on different layers in a staggered manner; shadowless glue layers are applied between the red LED layer 13, the green LED layer 16 and the blue LED layer 19, and simultaneously a metal film or an alloy film is fabricated around the LEDs on each shadowless glue layer. The metal film or the alloy film is carved or etched to form a conductive circuit;

A3. Re-apply a layer of shadowless glue 21;

A4. Stack the LED light-emitting control device layer 22, and fabricate the metal film 23 or alloy film around the LED light emitting control device. Carve or etch the metal film 23 or the alloy film to form a conductive circuit;

A5. Cover an encapsulated glue layer 24 above the LED light-emitting control device layer 22.

According to the embodiment of the invention, the translucent screen substrate is toughened glass or transparent plastic plate. The metal film or the alloy film is formed by utilizing the vacuum evaporation plating technology, magntron sputtering technology, continuous coating technology, hydro-electric coating technology or chemical coating technology. The encapsulated glue layer 24 is a shadowless glue layer.

Step A2 comprises steps:

B1. LED chips are sucked via the die bond and arranged and placed on the plane adhesive board. The plane adhesive board is buckled upside down on the shadowless glue layer for pressing and solidifying;

B2. The plane adhesive board is pulled out to ensure that all LED chips remain flush on the shadowless glue layer. Thus, no wire of the sputtered coating can be broken when the metal layer is sputtered.

The embodiment for the 3D encapsulation method of LED display screen module in the invention comprises the steps as follows:

1) Red, green and blue display chips are respectively encapsulated on the colloid surface by three layers according to the laws. The first layer is a red LED chip (large), the second layer a green LED chip (medium) and the third layer a blue LED chip (small), which are encapsulated by three layers, and then they are stacked and combined to achieve the display effect. The stacking mode is shown in FIG. 2;

2) A layer of UV glue (i.e. shadowless glue) with a thickness of 18-200 um is sprayed on the toughened glass substrate. The thickness of the UV glue is adjusted according to the thickness of the chip. The LED chips are sucked through die-bond equipment, and arranged and placed on a plane adhesive board and the plane adhesive board is buckled upside down on the shadowless glue layer for pressing and solidifying. The plane adhesive board is pulled out and the LED chips are then fixed on the glass substrate, thus ensuring that each LED chip remains flush on the shadowless glue layer to avoid the UV glue from covering the LED chips, and facilitate subsequent conductive film plating and carving and etching of the circuit communication.

3) The first layer of red LED chips is pressed and a layer of conductive film is coated on the back surface of the red LED chips. The surplus film is carved away to form the required conductive circuit, so that each LED chip can be communicated in series and an interface is reserved to be connected with the second layer of LED chips. After the circuit is fabricated, a layer of UV glue is sprayed to fix the green LED chips.

4) The green LED chips with fixed die bond are pressed again on the UV glue for polishing and fixing and a layer of conductive film is plated on the electrode surface of the green LED chip. The surplus film is carved away to form the required conductive circuit, so that each LED chip can be communicated in series and an interface is reserved to be connected with the third layer of LED chips. After the circuit is fabricated, a layer of UV glue is sprayed to fix the green LED chips.

5) The blue LED chips with fixed die bond are pressed again on the UV glue for polishing and fixing and a layer of conductive film is plated on the electrode surface of the green LED chip. The surplus film is carved away to form the required conductive circuit, so that each LED chip can be communicated in series and an interface is reserved to be connected with the third layer of LED chips. After the circuit is fabricated, a layer of UV glue is sprayed for purpose of protection, specifically as shown in FIG. 1.

6) According to the above operation, the invention can also directly encapsulate the digital signal processing (DSP) so that the encapsulated whole module is a finished product without external processing, and thus, it will save the cost and improve the efficiency. The specific operation is as follows:

6.1) The UV glue is sprayed on the encapsulated RGB module and then DSP electronic devices are placed and pressed on the UV glue, and then the conductive film is plated. The surplus conductive film is removed by laser etching technology to remain the circuit layer to be connected with the RGB reserved interface so as to achieve the encapsulation of the complete module.

7) A layer of protective glue is coated on the substrate to complete the encapsulation of LED display screen module.

Further, the conductive film is form in the step 2) or step 3) or step 4) by the sputtering technology.

Further, the material of conductive film in step 2) or step 3) or step 4) may be copper or tin or copper-tin alloy.

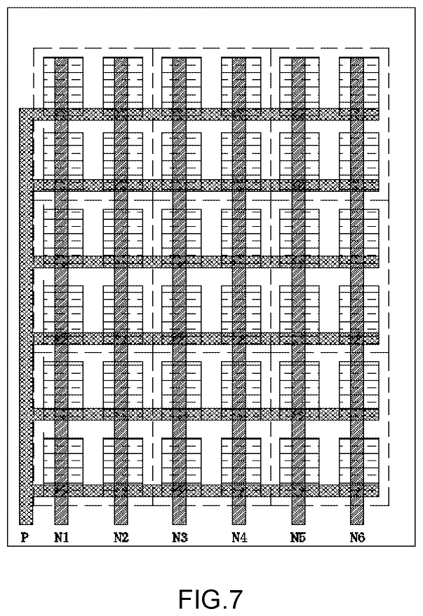

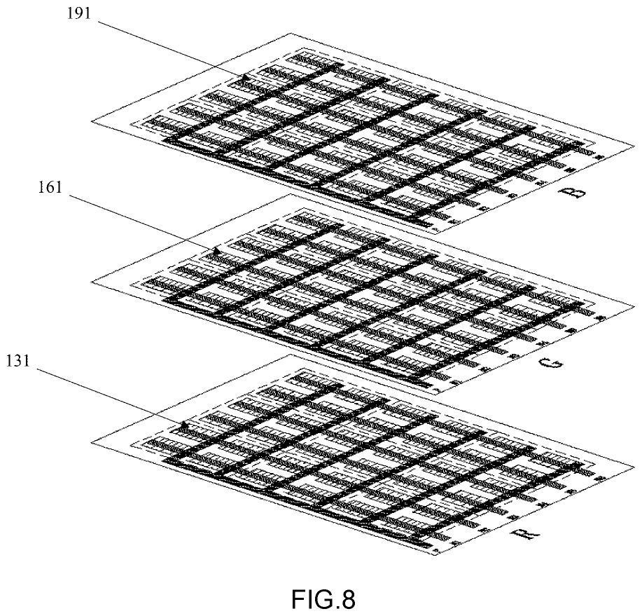

As shown in FIG. 1, FIG. 7, and FIG. 8, the LED display screen module stacked and encapsulated by blocks in the invention comprises a translucent screen substrate 11 on the surface of a display screen, wherein a red LED layer 13, a green LED layer 16, a blue LED layer 19 and an LED light emitting control device layer 22 positioned above the red LED layer 13, the green LED layer 16 and the blue LED layer 19 are sequentially stacked in any order on the translucent screen substrate 11. The red LED layer 13 consists of red LED chipset block 131 which can be transferred and placed integrally, the green LED layer 16 consists of green LED chipset block 161 which can be transferred and placed integrally, the blue LED layer 19 consists of blue LED chipset block 191 which can be transferred and placed integrally. The translucent screen substrate 11, the red light LED layer 13, the green light LED layer 16, the blue light LED layer 19 and the LED light emitting control device layer 22 are fixedly connected through the shadowless glue layers 12, 15, 18 and 21; the red LED layer 13, the green LED layer 16 and the blue LED layer 19 are coated with the metal films 14, 17, 20 and 23, respectively. Conductive circuits formed by carving or etching metal films or alloy films are laid on the red light LED layer, the green light LED layer, the blue light LED layer and the LED light emitting control device layer, and LEDs are arranged on different layers in a staggered manner. According to the embodiment of the invention, the translucent screen substrate 11 is a toughened glass or transparent plastic plate. The metal film or the alloy film is formed by utilizing the vacuum evaporation plating technology, magntron sputtering technology, continuous coating technology, hydro-electric coating technology or chemical coating technology. The conductive circuit is formed via the laser carving technology. LED light-emitting control device layer 22 is covered with the encapsulated glue layer 24.

The red LED chipset block 131, the green LED chipset block 161 and the blue LED chipset block 191 are respectively composed of 10*10, 20*20, 30*30 or 40*40 LED chips or they are the matrix modules composed of any columns X*rows Y. The red LED chipset block 131, the green LED chipset block 161, and the blue LED chipset block 191 are manufactured by using the photomask technology. Shallow channels are arranged on the peripheries of the red LED layer 13, the green LED layer 16, and the blue LED layer 19. Shallow channels are arranged on the peripheries of the red LED chipset block 131, the green LED chipset block 161, and the blue LED chipset block 191. A shallow channel is arranged around the LED chip. The red LED layer 13, the green LED layer 16, and the blue LED layer 19 are subject to positive pole common connection, while the red LED layer 13, the green LED layer 16, and the blue LED layer 19 are subject to negative pole common connection.

The encapsulation method of LED display screen module in the invention comprises the steps as follows:

C1. Apply a layer of shadowless glue 12 on the translucent screen substrate 11;

C2. The red LED layer 13 consists of red LED chipset block 131 which can be transferred and placed integrally, the green LED layer 16 consists of green LED chipset block 161 which can be transferred and placed integrally and the blue LED layer 19 consists of blue LED chipset block 191 which can be transferred and placed integrally.

C3. A red LED layer 13, a green LED layer 16 and a blue LED layer 19 are sequentially stacked in any order. Shadowless glue layers are applied between the red LED layer 13, the green LED layer 16 and the blue LED layer 19, and simultaneously a metal film or an alloy film is fabricated around the LEDs on each shadowless glue layer. The metal film or the alloy film is carved or etched to form a conductive circuit;

C4. Re-apply a layer of shadowless glue 21;

C5. Stack the LED light-emitting control device layer 22, and simultaneously fabricate the metal film 23 or alloy film around the LED light emitting control device. Carve or etch the metal film 23 or the alloy film to form a conductive circuit;

C6. Cover an encapsulated glue layer 24 above the LED light-emitting control device layer 22.

According to embodiments of the invention, the conductive circuits are formed by laser carving technology. The encapsulation glue layer 24 is a shadowless glue layer, and the metal film 23 or alloy film is formed by vacuum sputtering technology. The metal film 23 may be made of copper, tin, aluminum, gold, etc. Then, the circuit is etched by laser etching to remove excess metal to form the conductive circuit so that each layer of LED chips are communicated and connected to achieve bonding-wire-free encapsulation.

Those skilled in the art can achieve the invention through various modifications without departing from the essence and spirit of the invention. The above instruction is only a preferred and feasible embodiment of the invention, and is not intended to limit the scope of the rights of the invention. All equivalent structural changes made using the instructions and drawings of the invention are included in the scope of the rights of the invention.

What is claimed is:

1. The invention relates to a 3D stacked encapsulated LED display screen module, which is characterized in that it comprises a translucent screen substrate on the surface of a display screen, wherein a red LED layer, a green LED layer, a blue LED layer and an LED light emitting control device layer positioned above the red LED layer, the green LED layer and the blue LED layer are sequentially stacked in any order on the translucent screen substrate. The translucent screen substrate, the red light LED layer, the green light LED layer, the blue light LED layer and the LED light emitting control device layer are fixedly connected through shadowless glue layers; Conductive circuits formed by carving or etching metal films or alloy films are laid on the red light LED layer, the green light LED layer, the blue light LED layer and the LED light emitting control device layer, and LEDs are arranged on different layers in a staggered manner.

2. A 3D stacked encapsulated LED display screen module presented in claim 1, which is characterized in that the translucent screen substrate is toughened glass or transparent plastic plate.

3. A3D stacked encapsulated LED display screen module presented in claim 1, which is characterized in that the metal film or the alloy film is formed by utilizing the vacuum evaporation plating technology, magntron sputtering technology, continuous coating technology, hydro-electric coating technology or chemical coating technology.

4. A3D stacked encapsulated LED display screen module presented in claim 1, which is characterized in that the conductive circuit is formed via the laser engraving.

5. A 3D stacked encapsulated LED display screen module presented in claim 1, which is characterized in that the LED light-emitting control device layer is covered with the encapsulated glue layer.

6. An encapsulation method of an LED display screen module, which is characterized in that it comprises the following steps:
A1. Apply a layer of shadowless glue on the translucent screen substrate;
A2. A red LED layer, a green LED layer and a blue LED layer are sequentially stacked in any order, wherein LEDs on different layers are arranged in a staggered manner; shadowless glue layers are applied between the red LED layer, the green LED layer and the blue LED layer, and simultaneously a metal film or an alloy film is fabricated around the LEDs on each shadowless glue layer. The metal film or the alloy film is carved or etched to form a conductive circuit;
A3. Re-apply a layer of shadowless glue;
A4. Stack the LED light-emitting control device layer, and fabricate the metal film or alloy film around the LED light emitting control device. Carve or etch the metal film or the alloy film to form a conductive circuit;
A5. Cover an encapsulated glue layer above the LED light-emitting control device layer.

7. An encapsulation method of LED display screen module presented in claim 6, which is characterized in that the translucent screen substrate is toughened glass or transparent plastic plate.

8. An encapsulation method for LED display screen module presented in claim 7, which is characterized in that the metal film or the alloy film is formed by utilizing the vacuum evaporation plating technology, magntron sputtering technology, continuous coating technology, hydro-electric coating technology or chemical coating technology.

9. An encapsulation method of LED display screen module presented in claim 8, which is characterized in that the conductive circuit is formed via the laser carving technology.

10. An encapsulation method of LED display screen module presented in claim 9, which is characterized in that the encapsulating glue layer is a shadowless glue layer.

11. An encapsulation method of LED display screen module presented in claim 6, which is characterized in that Step A2 contains the following steps:
B1. LED chips are sucked via the die bond and arranged and placed on the plane adhesive board. The plane adhesive board is buckled upside down on the shadowless glue layer for pressing and solidifying;
B2. The plane adhesive board is pulled out to ensure that all LED chips remain flush on the shadowless glue layer.

12. A LED display screen module stacked and encapsulated by blocks, which is characterized in that it contains the translucent screen substrate on the surface of display screen. wherein a red LED layer, a green LED layer, a blue LED layer and an LED light emitting control device layer positioned above the red LED layer, the green LED layer and the blue LED layer are sequentially stacked in any order on the translucent screen substrate. The red LED layer consists of a red LED chip set block which can be transferred and placed integrally, the green LED layer consists of a green LED chip set block which can be transferred and placed integrally, the blue LED layer consists of a blue LED chip set block which can be transferred and placed integrally. The translucent screen substrate, the red light LED layer, the green light LED layer, the blue light LED layer and the LED light emitting control device layer are fixedly connected through shadowless glue layers; Conductive circuits formed by carving or etching metal films or alloy films are laid on the red light LED layer, the green light LED layer, the blue light LED layer and the LED light emitting control device layer.

13. A LED display screen module stacked and encapsulated by blocks presented in claim 12, which is characterized in that the red LED chipset, the green LED chipset and the blue LED chipset are composed of LED chips of 10*10, 20*20, 30*30 or 40*40, respectively.

14. A LED display screen module stacked and encapsulated by blocks presented in claim 12, which is characterized in that the red LED chipset block, the green LED chipset block and the blue LED chipset block are manufactured by adopting a photomask technology.

15. A LED display screen module stacked and encapsulated by blocks presented in claim 12, which is characterized in that shallow channels are arranged on the peripheries of the red LED layer, the green LED layer and the blue LED layer.

16. A LED display screen module stacked and encapsulated by blocks presented in claim 12, which is characterized in that shallow channels are arranged on the peripheries of the red LED chipset block, the green LED chipset block and the blue LED chipset block.

17. A LED display screen module stacked and encapsulated by blocks presented in claim 12, which is characterized in that shallow channels are arranged on the periphery of the LED chipset.

18. A LED display screen module stacked and encapsulated by blocks presented in claim 12, which is characterized in that LED chips on the red LED layer, the green LED layer and the blue LED layer are subject to the positive pole common connection, and each row or each column of LED chips on the red LED layer, the green LED layer and the blue LED layer are subject to the negative pole common connection.

19. An encapsulation method of LED display screen module, which is characterized in that it comprises the steps:
C1. Apply a layer of shadowless glue on the translucent screen substrate;
C2. The red LED layer consists of a red LED chip set block which can be transferred and placed integrally, the green LED layer consists of a green LED chip set block which can be transferred and placed integrally and the blue LED layer consists of a blue LED chip set block which can be transferred and placed integrally.
C3. A red LED layer, a green LED layer and a blue LED layer are sequentially stacked in any order. Shadowless glue layers are applied between the red LED layer, the green LED layer and the blue LED layer, and simultaneously a metal film or an alloy film is fabricated around the LEDs on each shadowless glue layer. The metal film or the alloy film is carved or etched to form a conductive circuit;
C4. Re-apply a layer of shadowless glue;
C5. Stack the LED light-emitting control device layer, and fabricate the metal film or alloy film around the LED light emitting control device. Carve or etch the metal film or the alloy film to form a conductive circuit;
C6. Cover an encapsulated glue layer above the LED light-emitting control device layer.
